(19) United States
(12) Patent Application Publication
(10) Pub. No.: US 2014/0050018 A1
(43) Pub. Date: Feb. 20, 2014

(54) SEMICONDUCTOR MEMORY DEVICE

(71) Applicant: KABUSHIKI KAISHA TOSHIBA, Tokyo (JP)

(72) Inventors: Tsuyoshi MIDORIKAWA, Kanagawa (JP); Nobuaki OTSUKA, Tokyo (JP)

(73) Assignee: KABUSHIKI KAISHA TOSHIBA, Tokyo (JP)

(21) Appl. No.: 13/787,652

(22) Filed: Mar. 6, 2013

(30) Foreign Application Priority Data
Aug. 14, 2012 (JP) 2012-179723

(51) Int. Cl. G11C 11/419

(52) U.S. Cl. CPC G11C 11/419
USPC 365/156

(57) ABSTRACT

According to one embodiment, a semiconductor memory device includes a memory cell provided with a pair of storage nodes which store data in a complementary manner, a pair of bit lines that are driven in a complementary manner based on data written to the memory cell, a word line that selects a row of the memory cell, and a word line potential fixing circuit that fixes a potential of the word line so that the row of the memory cell is not selected when a power supply of the memory cell rises.

### CROSS-REFERENCE TO RELATED APPLICATIONS

This application is based upon and claims the benefit of priority from Japanese Patent Application No. 2012-179723, filed on Aug. 14, 2012; the entire contents of which are incorporated herein by reference.

### FIELD

Embodiments described herein relate generally to a semiconductor memory device.

### BACKGROUND

In an SRAM, when a word line is in a floating state at the time of rising of a power supply voltage, a potential of the word line increases as the power supply voltage increases. Therefore, charges accumulated in a bit line are discharged through a memory cell and a rush current increases, so that it may be difficult for the power supply voltage to rise.

### BRIEF DESCRIPTION OF THE DRAWINGS

FIG. 1 is a block diagram illustrating a schematic configuration of a semiconductor memory device according to a first embodiment;

FIG. 2 is a circuit diagram illustrating a specific example of one column of the semiconductor memory device of FIG. 1;

FIG. 3 is a block diagram illustrating a method of generating a control signal WLP of FIG. 2;

FIG. 4 is a timing chart illustrating a relationship between the control signal WLP and a word line potential WL when a power supply voltage of the semiconductor memory device of FIG. 1 rises;

FIG. 5 is a block diagram illustrating a schematic configuration of a semiconductor memory device according to a second embodiment;

FIG. 6 is a circuit diagram illustrating a specific example of one column of the semiconductor memory device of FIG. 5; and

FIG. 7 is a timing chart illustrating a relationship between power supply voltages VDD and VDDWL and a word line potential WL when a power supply voltage of the semiconductor memory device of FIG. 5 rises.

### DETAILED DESCRIPTION

In general, according to one embodiment, a memory cell, a pair of bit lines, a word line, and a word line potential fixing circuit are provided. The memory cell is provided with a pair of storage nodes which store data in a complementary manner. The pair of bit lines are driven in a complementary manner based on data written to the memory cell. The word line selects a row of the memory cell. The word line potential fixing circuit fixes a potential of the word line so that a row of the memory cells is not selected when a power supply voltage of the memory cells rises.

Hereinafter, semiconductor memory devices according to embodiments will be described in detail with reference to the accompanying drawings. These embodiments do not limit the present invention.

### First Embodiment

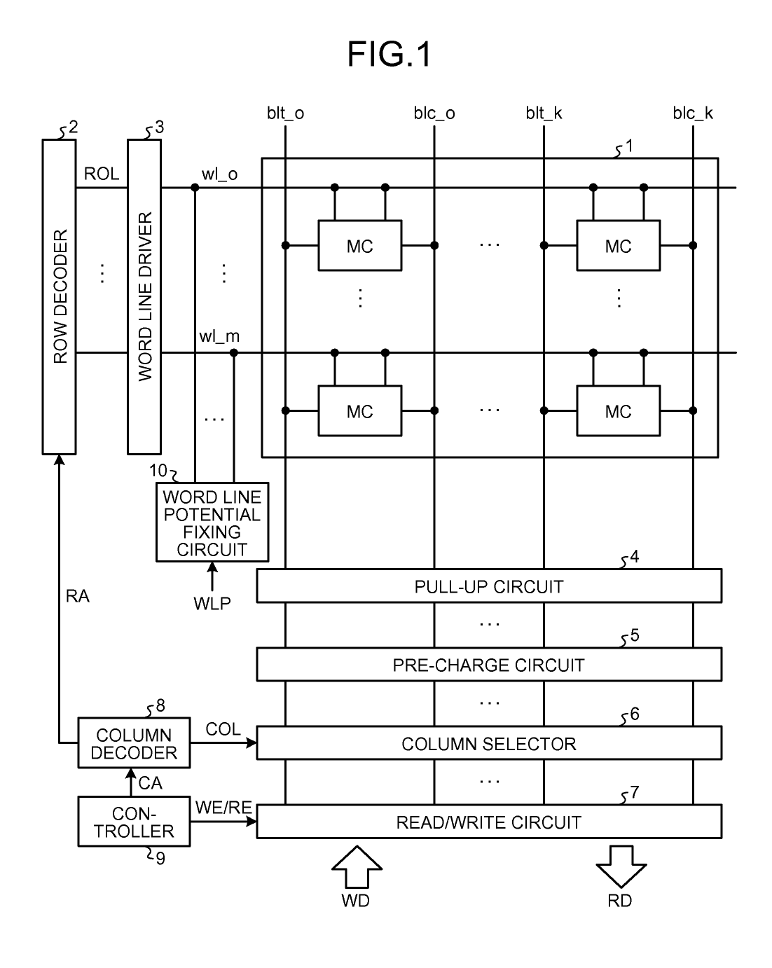

FIG. 1 is a block diagram illustrating a schematic configuration of a semiconductor memory device according to a first embodiment.

In FIG. 1, the semiconductor memory device includes a memory cell array 1, a row decoder 2, a word line driver 3, a pull-up circuit 4, a pre-charge circuit 5, a column selector 6, a read/write circuit 7, a column decoder 8, a controller 9, and a word line potential fixing circuit 10.

Here, in the memory cell array 1, memory cells MC are arranged in a matrix form in a row direction and a column direction. The memory cell MC can store data in a complementary manner. For example, an SRAM cell can be used as the memory cell MC. The memory cell array 1 is provided with word lines wl_0 to wl_m (m is a positive integer) to select a row of a memory cell MC for each row and bit lines blt_0 to blt_k and blc_0 to blc_k (k is a positive integer) to select a column of a memory cell MC for each column.

The row decoder 2 can generate a row selection signal ROL to select a row of a memory cell MC based on a row address RA. The word line driver 3 can drive the word lines wl_0 to wl_m specified by the row selection signal ROL. The pull-up circuit 4 can pull up potentials of the bit lines blt_0 to blt_k and blc_0 to blc_k to the power supply voltage VDD in a complementary manner. The pre-charge circuit 5 can pre-charge the bit lines blt_0 to blt_k and blc_0 to blc_k to the high level before reading data from the memory cell MC. The column selector 6 can connect the bit lines blt_0 to blt_k and blc_0 to blc_k specified by a column selection signal COL to the read/write circuit 7. The read/write circuit 7 can input write data WD based on a write enable signal WE and output read data RD based on a read enable signal RE. As the read circuit, a sense amplifier can be used which detects data stored in a memory cell MC based on a signal read from the memory cell MC to the bit lines blt_0 to blt_k and blc_0 to blc_k. As the write circuit, a write amplifier can be used which drives the bit lines blt_0 to blt_k and the bit lines blc_0 to blc_k in a complementary manner to each other according to the write data WD. The column decoder 8 can generate a column selection signal COL to select a column of a memory cell MC based on a column address CA. The controller 9 can control operation timing of the row decoder 2, the column decoder 8, the read/write circuit 7, and the like. The word line potential fixing circuit 10 can fix potentials of the word lines wl_0 to wl_m to the low level so that a row of the memory cells MC is not selected when the power supply voltage of the memory cells MC rises. The word line potential fixing circuit 10 can release the fixation of the potentials of the word lines wl_0 to wl_m when the power supply voltage of the memory cells MC rises.

A power supply can be shared by the memory cell array 1, the row decoder 2, the word line driver 3, the pull-up circuit 4, the pre-charge circuit 5, the column selector 6, the read/write circuit 7, the column decoder 8, and the controller 9.

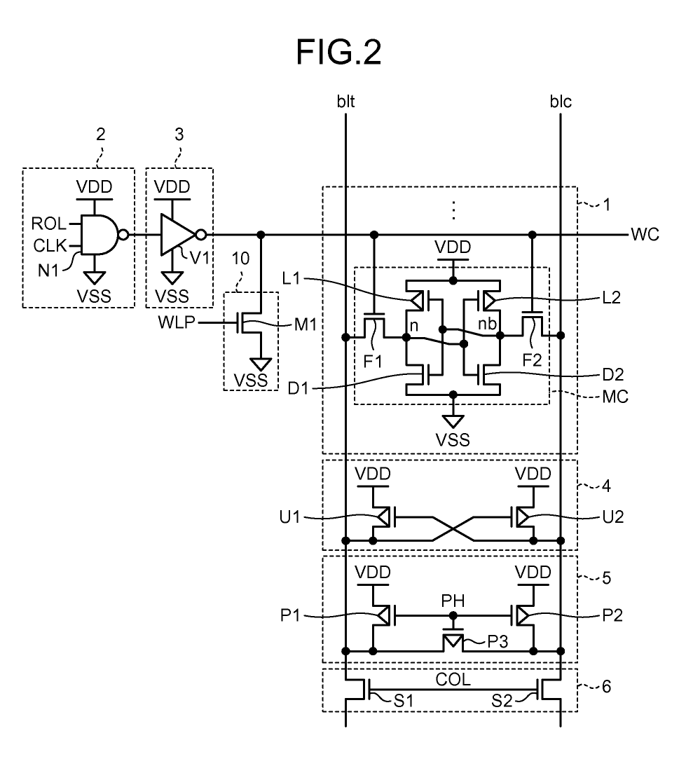

FIG. 2 is a circuit diagram illustrating a specific example of one column of the semiconductor memory device of FIG. 1.

In FIG. 2, a memory cell MC includes a pair of drive transistors D1 and D2, a pair of load transistors L1 and L2, and a pair of transfer transistors F1 and F2. As the load transistors L1 and L2, p-channel field-effect transistors can be used. As the drive transistors D1 and D2 and the transfer transistors F1 and F2, n-channel field-effect transistors can be used.

The drive transistor D1 and the load transistor L1 are connected in series with each other, so that a CMOS inverter is formed, and also the drive transistor D2 and the load transistor L2 are connected in series with each other, so that a CMOS inverter is formed. The output and input of the pair of CMOS inverters are cross-coupled to each other, so that a flip-flop is formed. The word line wl is connected to the gates of the transfer transistors F1 and F2.

The connection point between the drain of the drive transistor D1 and the drain of the load transistor L1 can form a storage node n and the connection point between the drain of the drive transistor D2 and the drain of the load transistor L2 can form a storage node nb.

The bit line blt is connected to the storage node n through the transfer transistor F1. The bit line blc is connected to the storage node nb through the transfer transistor F2. The sources of the load transistors L1 and L2 are connected to the power supply voltage VDD and the sources of the drive transistors D1 and D2 are connected to the ground potential VSS.

The row decoder 2 is provided with a NAND circuit N1 for each row. The row selection signal ROL is inputted into one input terminal of the NAND circuit N1 and a clock signal CLK is inputted into the other input terminal of the NAND circuit N1. The power supply of the NAND circuit N1 is connected to the power supply voltage VDD.

The word line driver 3 is provided with an inverter V1 for each row. The input terminal of the inverter V1 is connected to the output terminal of the NAND circuit N1 and the output terminal of the inverter V1 is connected to the word line wl.

The word line potential fixing circuit 10 is provided with a potential fixing transistor M1 for each row. As the potential fixing transistor M1, an n-channel field-effect transistor can be used. The drain of the potential fixing transistor M1 is connected to the word line wl and the source of the potential fixing transistor M1 is connected to the ground potential VSS. A control signal WLP is inputted into the gate of the potential fixing transistor M1. The control signal WLP can be activated even when the power supply voltage VDD is turned off. The control signal WLP can be generated by a power supply other than the power supply voltage VDD. The control signal WLP can be commonly used for all the rows in the memory cell array 1.

The pull-up circuit 4 is provided with pull-up transistors U1 and U2 for each column. As the pull-up transistors U1 and U2, p-channel field-effect transistors can be used. The gate of the pull-up transistor U1 is connected to the bit line blc, the source of the pull-up transistor U1 is connected to the bit line blt, and the drain of the pull-up transistor U1 is connected to the power supply voltage VDD. The gate of the pull-up transistor U2 is connected to the bit line blt, the source of the pull-up transistor U2 is connected to the bit line blc, and the drain of the pull-up transistor U2 is connected to the power supply voltage VDD.

The pre-charge circuit 5 is provided with pre-charge transistors P1 to P3. As the pre-charge transistors P1 to P3, p-channel field-effect transistors can be used. The sources of the pre-charge transistors P1 and P2 are connected to the power supply voltage VDD, the drain of the pre-charge transistor P1 is connected to the bit line blt, and the drain of the pre-charge transistor P2 is connected to the bit line blc. The pre-charge transistor P3 is connected between the bit lines blt and blc. A pre-charge signal PH is inputted into the gates of the pre-charge transistors P1 to P3.

The column selector 6 is provided with select transistors S1 and S2. As the select transistors S1 and S2, n-channel or p-channel field-effect transistors can be used. The drain of the select transistor S1 is connected to the bit line blt and the drain of the select transistor S2 is connected to the bit line blc. The sources of the select transistors S1 and S2 are connected to the read/write circuit 7. The column selection signal COL is inputted into the gates of the select transistors S1 and S2.

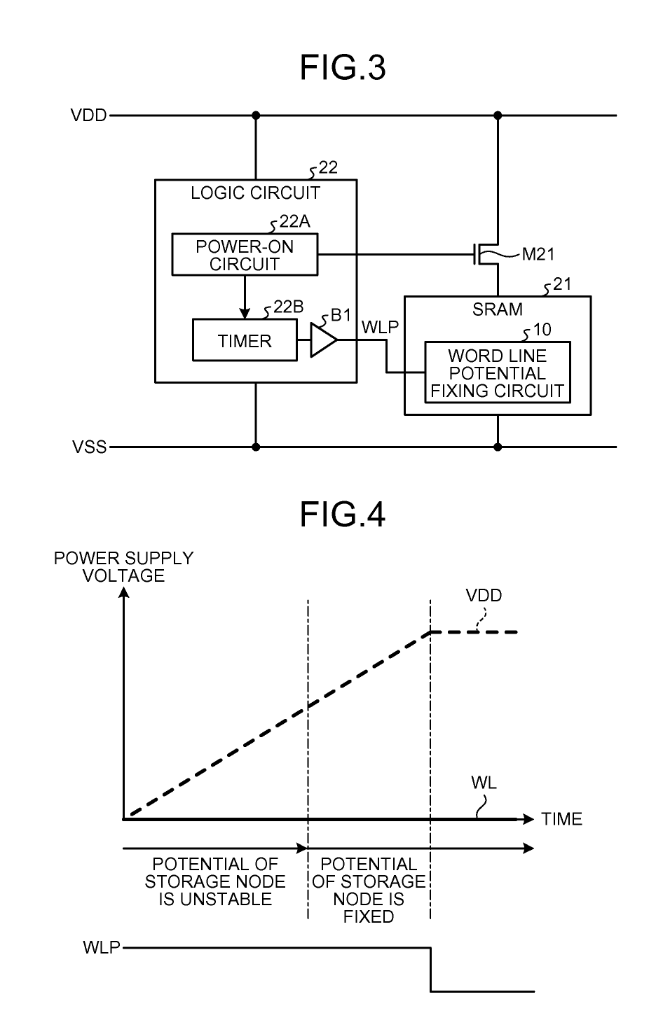

FIG. 3 is a block diagram illustrating a generation method of the control signal WLP of FIG. 2.

In FIG. 3, an SRAM 21 is provided with the word line potential fixing circuit 10 of FIG. 1. Here, the power supply of the SRAM 21 can be connected to the power supply voltage VDD through a power-on transistor M21. As the power-on transistor M21, an n-channel field-effect transistor can be used.

On the other hand, a logic circuit 22, which performs power supply control of the SRAM 21, is provided with a power-on circuit 22A, a timer 22B, and a buffer B1. The power-on circuit 22A can turn on the power supply of the SRAM 21. The timer 22B can measure the ramp-up time of the power supply of the SRAM 21. The buffer B1 can drive the gate of the potential fixing transistor M1 of FIG. 2. The power supply of the logic circuit 22 can be connected to the power supply voltage VDD.

When the SRAM 21 is in a power saving mode, the power supply of the SRAM 21 is turned off when the power-on transistor M21 is turned off through the power-on circuit 22A. At this time, the control signal WLP is set to the high level through the buffer B1 and the potential fixing transistor M1 is turned on. Therefore, the potential of the word line wl is set to the ground potential VSS through the potential fixing transistor M1 and the transfer transistors F1 and F2 are fixed to off.

While the power supply voltage of the SRAM 21 is rising, when the power-on transistor M21 is turned on through the power-on circuit 22A, the power supply voltage is supplied to the SRAM 21. At this time, when a count operation of the timer 22B is started and the timer 22B counts up, the control signal WLP is set to the low level through the buffer B1 and the potential fixing transistor M1 is turned off. The time that elapses before the timer 22B counts up can be set to the time that elapses before the power supply of the memory cell MC rises to the power supply voltage VDD. When the power supply of the memory cell MC rises to the power supply voltage VDD, the potentials of the storage nodes n and nb are fixed.

After the power supply of the memory cell MC rises to the power supply voltage VDD and before the write enable signal WE rises, the potential of the word line wl and the pre-charge signal PH are set to the low level. Therefore, the transfer transistors F1 and F2 are turned off, so that the storage nodes n an nb are separated from the bit lines blt and blc respectively, and the pre-charge transistors P1 to P3 are turned on, so that the bit lines blt and blc are pre-charged to the power supply voltage VDD.

In a selected column, the column selection signal COL rises, so that the select transistors S1 and S2 are turned on and the bit lines blt and blc of the selected column are connected to the read/write circuit 7. The pre-charge signal PH rises, so that the pre-charge transistors P1 to P3 are turned off and the potentials of the bit lines blt and blc are set to the low level or the high level according to the write data WD. At this time, if the potential of the bit line blt is set to the low level, the pull-up transistor U2 is turned on and the potential of the bit line blc is pulled up to the power supply voltage VDD through the pull-up transistor U2. On the other hand, if the potential of the bit line blc is set to the low level, the pull-up transistor U1 is turned on and the potential of the bit line blt is pulled up to the power supply voltage VDD through the pull-up transistor U1.

In a selected row, the row selection signal ROL rises, so that the potential of the word line wl rises. Therefore, the transfer transistors F1 and F2 are turned on and the storage nodes n and nb are connected to the bit lines blt and blc respectively, so that the write data WD is written to the storage nodes n an nb in a selected sel.

FIG. 4 is a timing chart illustrating a relationship between the control signal WLP and a word line potential WL when the power supply voltage of the semiconductor memory device of FIG. 1 rises.

In FIG. 4, while the power supply of the memory cell MC is rising, before the power supply of the memory cell MC rises to the power supply voltage VDD, the potentials of the storage nodes n and nb are unstable. At this time, the control signal WLP is set to the high level through the buffer B1 and the potential fixing transistor M1 is turned on. Therefore, the potential of the word line wl is set to the ground potential VSS through the potential fixing transistor M1 and the transfer transistors F1 and F2 are fixed to off. As a result, even when electric charges are charged in the bit line blt and blc, it is possible to prevent the electric charges from being discharged through the memory cell MC. Therefore, it is possible to prevent the rush current from increasing when the power supply of the memory cell MC rises, so that it is possible to stably boost the power supply of the memory cell MC.

When the power supply of the memory cell MC rises to the power supply voltage VDD, the potentials of the storage nodes n and nb are fixed. After the power supply of the memory cell MC rises to the power supply voltage VDD, the control signal WLP is set to the low level, so that the potential fixing transistor M1 is turned off and a row can be selected through the word line wl.

### Second Embodiment

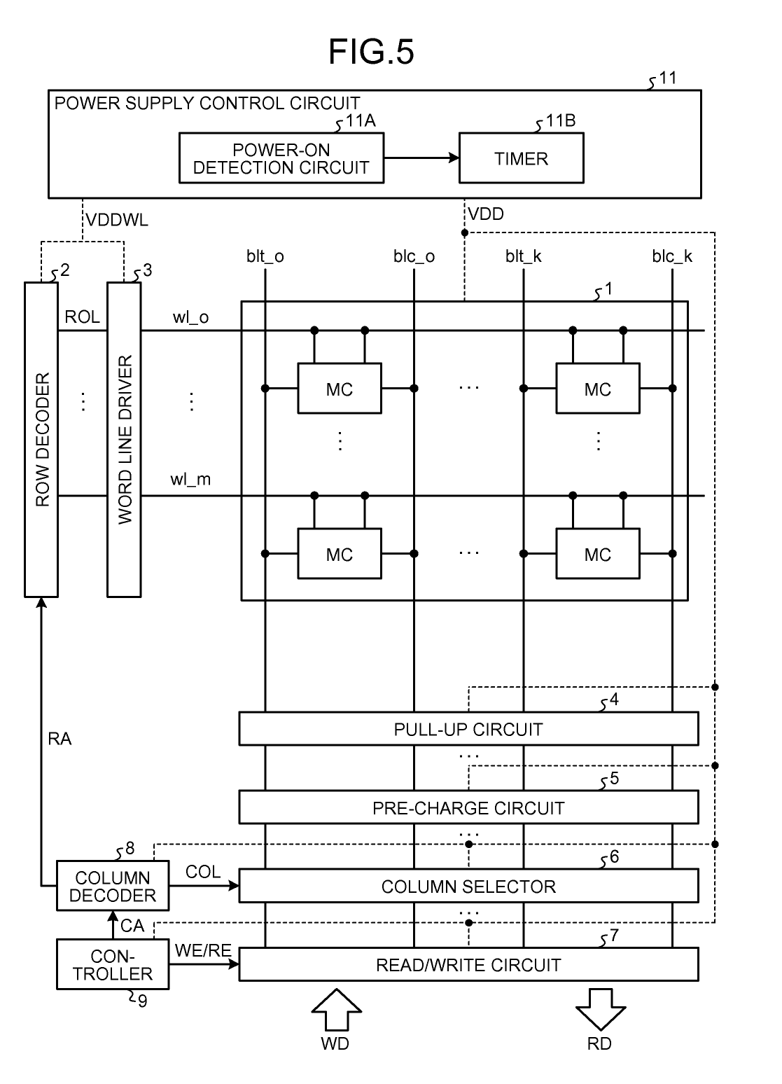

FIG. 5 is a block diagram illustrating a schematic configuration of a semiconductor memory device according to a second embodiment.

In FIG. 5, the semiconductor memory device is provided with a power supply control circuit 11 instead of the word line potential fixing circuit 10 of FIG. 1. The power supply control circuit 11 can boost the power supply voltage VDD of the memory cell MC after boosting a power supply voltage VDDWL that fixes the potentials of the word lines wl_0 to wl_m so that a row of the memory cells MC is not selected. Here, the power supply control circuit 11 is provided with a power-on detection circuit 11A and a timer 11B. The power-on detection circuit 11A can detect power-on of the power supply voltage VDDWL. The timer 11B can measure the ramp-up time of the power supply voltage VDDWL.

The power supply voltage VDDWL is supplied to the row decoder 2 and the word line driver 3. The power supply voltage VDD is supplied to the memory cell array 1, the pull-up circuit 4, the pre-charge circuit 5, the column selector 6, the read/write circuit 7, the column decoder 8, and the controller 9.

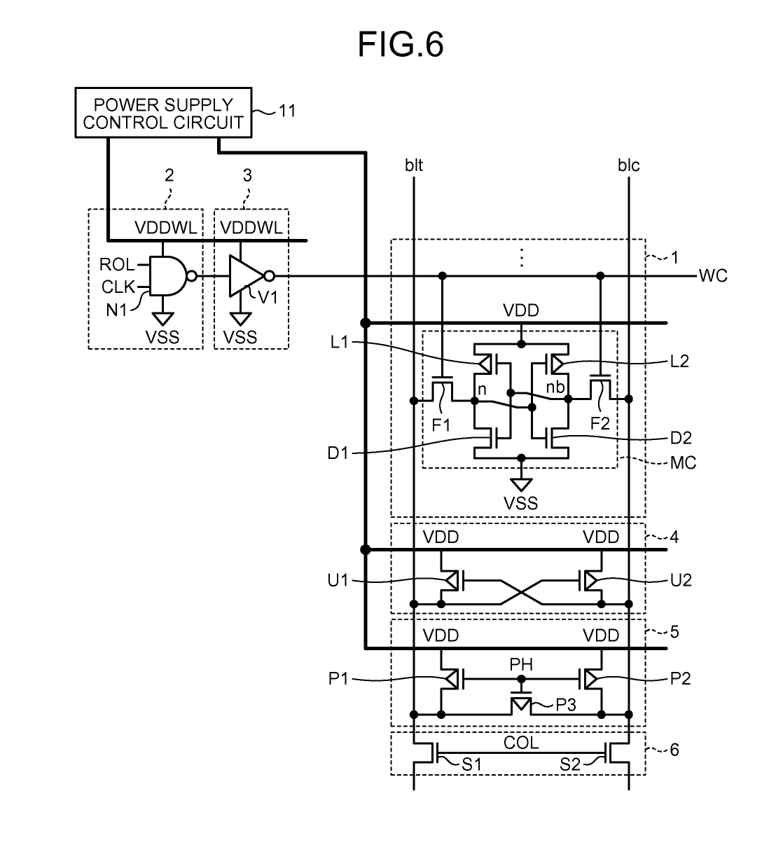

FIG. 6 is a circuit diagram illustrating a specific example of one column of the semiconductor memory device of FIG. 5.

In FIG. 6, the semiconductor memory device is provided with the power supply control circuit 11 instead of the word line potential fixing circuit 10 of FIG. 2 for each column. While the power supply voltage VDD is supplied to the power supplies of the row decoder 2 and the word line driver 3 of FIG. 2, the power supply voltage VDDWL is supplied to the row decoder 2 and the word line driver 3 of FIG. 6.

When the power supply control circuit 11 boosts the power supply voltage VDD of the memory cell MC, the power supply control circuit 11 boosts the power supply voltage VDDWL of the row decoder 2 and the word line driver 3 before boosting the power supply voltage VDD of the memory cell MC.

Here, when the power supply voltage VDDWL of the row decoder 2 and the word line driver 3 is boosted, the potential of the word line wl can be set to the ground potential VSS through the row decoder 2 and the word line driver 3, so that the transfer transistors F1 and F2 can be fixed to off.

At this time, if the power-on detection circuit 11A detects power-on of the power supply voltage VDDWL, a count operation of the timer 11B is started. When the timer 11B counts up, a boost of the power supply voltage VDD of the memory cell MC is started. The time that elapses before the timer 11B counts up can be set to the time that elapses before the power supply voltage VDDWL rises. When the power supply of the memory cell MC rises to the power supply voltage VDD, the potentials of the storage nodes n and nb are fixed.

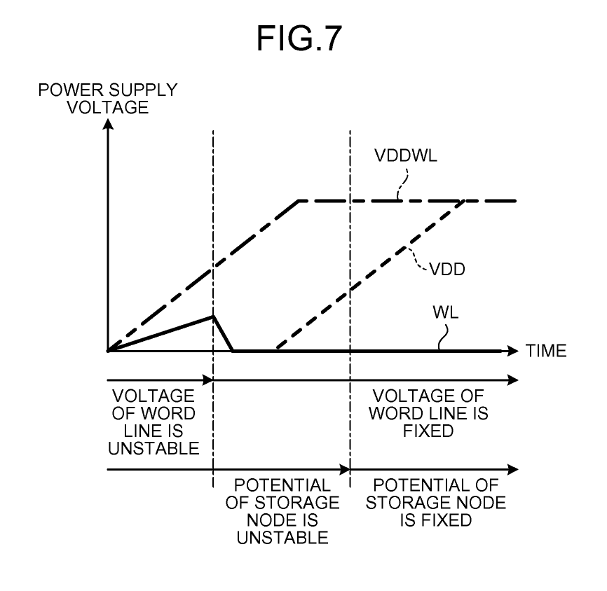

FIG. 7 is a timing chart illustrating a relationship between the power supply voltages VDD and VDDWL and the word line potential WL when the power supply of the semiconductor memory device of FIG. 5 rises.

In FIG. 7, while the power supply voltage VDDWL is rising, the voltage of the word line wl is unstable and the voltage of the word line wl rises as the power supply voltage VDDWL rises. Therefore, the transfer transistors F1 and F2 are turned on as the voltage of the word line wl rises. While the power supply of the memory cell MC is rising, before the power supply of the memory cell MC rises to the power supply voltage VDD, the potentials of the storage nodes n and nb are unstable. At this time, the power supply voltage VDD does not rise before the power supply voltage VDDWL rises, so that it is possible to prevent electric charges from being charged in the bit lines blt and blc. As a result, even when the transfer transistors F1 and F2 are turned on, it is possible to prevent electric charges from being discharged from the bit line blt and blc through the memory cell MC.

When the power supply voltage VDDWL rises, the voltage of the word line wl can be set to the ground potential VSS through the row decoder 2 and the word line driver 3, so that the transfer transistors F1 and F2 can be fixed to off. The power supply voltage VDD rises after the power supply voltage VDDWL rises, so that the potentials of the storage nodes n and nb are fixed. At this time, the voltage of the word line wl is set to the ground potential VSS through the row decoder 2 and the word line driver 3, so that it is possible to prevent the rush current from increasing when the power supply of the memory cell MC rises and it is also possible to stably boost the power supply of the memory cell MC.

In the embodiment described above, a method is described in which the power supply voltage VDDWL of the row decoder 2 and the word line driver 3 is provided from a power supply different from that of the power supply voltage VDD of the memory cell MC. However, the power supply voltage VDDWL of the row decoder 2, the word line driver 3, and controller 9 may be provided from a power supply different from that of the power supply voltage VDD of the memory cell MC.

Or, a power supply that charges the bit lines blt and blc may be provided separately from the power supply of the memory cell MC and the power supply of the memory cell MC may be boosted before the power supply that charges the bit lines blt and blc is boosted. For example, a power supply of the pull-up circuit 4 and the pre-charge circuit 5 may be provided separately from the power supply of the memory cell MC and the power supply of the memory cell MC may be boosted before the power supply of the pull-up circuit 4 and the pre-charge circuit 5 is boosted.

Here, the power supply of the memory cell MC is boosted before the power supply of the pull-up circuit 4 and the pre-charge circuit 5 is boosted, so that it is possible to fix the potentials of the storage nodes n and nb before electric charges are charged in the bit lines blt and blc and it is also possible to prevent the rush current from increasing when the power supply of the memory cell MC rises.

Or, a power supply that fixes the potential of the word line wl, a power supply that charges the bit lines blt and blc, and the power supply of the memory cell MC may be provided separately from each other, and the power supply that fixes the potential of the word line wl may be boosted before the power supply of the memory cell MC is boosted or the power supply of the memory cell MC may be boosted before the power supply that charges the bit lines is boosted.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a memory cell provided with a pair of storage nodes which store data in a complementary manner;
a pair of bit lines that are driven in a complementary manner based on data written to the memory cell;
a word line that selects a row of the memory cell; and
a word line potential fixing circuit that fixes a potential of the word line so that the row of the memory cell is not selected when a power supply of the memory cell rises.

2. The semiconductor memory device according to claim 1, wherein the word line potential fixing circuit includes a potential fixing transistor that fixes the potential of the word line to a low level based on a control signal when the power supply of the memory cell rises.

3. The semiconductor memory device according to claim 2, further comprising
a logic circuit that outputs the control signal until the power supply of the memory cell rises while the power supply of the memory cell is turned off.

4. The semiconductor memory device according to claim 3, wherein the logic circuit includes
a power-on circuit that turns on a power supply voltage supplied to the memory cell when the power supply voltage of the memory cell rises, and
a timer that measures a ramp-up time of the power supply voltage of the memory cell.

5. The semiconductor memory device according to claim 1, further comprising:
a row decoder that selects the word line for each row; and
a word line driver that drives the word line selected by the row decoder,
wherein the word line potential fixing circuit releases fixation of the potential of the word line so that the word line driver can drive the word line after the power supply of the memory cell rises.

6. The semiconductor memory device according to claim 5, wherein
the word line driver includes an inverter whose output is connected to the word line, and
the row decoder, whose output is connected to an input of the inverter, includes a NAND circuit that performs a negative AND operation between a row selection signal and a clock signal.

7. The semiconductor memory device according to claim 5, wherein the memory cell includes
a first CMOS inverter in which a first drive transistor and a first load transistor are connected in series with each other,
a second CMOS inverter in which a second drive transistor and a second load transistor are connected in series with each other,
a first transfer transistor connected between a first storage node provided at a connection point between the first drive transistor and the first load transistor and a first bit line, and
a second transfer transistor connected between a second storage node provided at a connection point between the second drive transistor and the second load transistor and a second bit line,
wherein output and input of the first CMOS inverter and the second CMOS inverter are cross-coupled to each other, and
a gate of the first transfer transistor and a gate of the second transfer transistor are connected to the word line.

8. The semiconductor memory device according to claim 7, wherein
potentials of the first and second storage nodes are unstable before the power supply of the memory cell rises to the power supply voltage, and
the word line potential fixing circuit fixes the potential of the word line while the potentials of the first and second storage nodes are unstable and releases fixation of the potential of the word line after the potentials of the first and second storage nodes are fixed.

9. The semiconductor memory device according to claim 8, further comprising:
a pull-up circuit that pulls up potentials of the bit lines in a complementary manner;
a pre-charge circuit that pre-charges the bit lines to a high level before reading data from the memory cell;
a read/write circuit that inputs write data based on a write enable signal and outputs read data based on a read enable signal; and
a column selector that connects a bit line specified by a column selection signal to the read/write circuit,
wherein a power supply is shared by the memory cell, the row decoder, the word line driver, the pull-up circuit, the pre-charge circuit, the column selector, the read/write circuit, and the column decoder.

10. A semiconductor memory device comprising:
a memory cell provided with a pair of storage nodes which store data in a complementary manner;
a pair of bit lines that are driven in a complementary manner based on data written to the memory cell;
a word line that selects a row of the memory cell; and
a power supply control circuit that boosts a second power supply of the memory cell after boosting a first power supply that fixes potentials of the word lines so that a row of the memory cell is not selected.

11. The semiconductor memory device according to claim 10, further comprising:
a row decoder that selects the word line for each row; and
a word line driver that drives the word line selected by the row decoder,
wherein the power supply control circuit boosts the second power supply of the memory cell after boosting the first power supply of the row decoder and the word line driver.

12. The semiconductor memory device according to claim 11, wherein
the word line driver includes an inverter whose output is connected to the word line, and
the row decoder, whose output is connected to an input of the inverter, includes a NAND circuit that performs a negative AND operation between a row selection signal and a clock signal.

13. The semiconductor memory device according to claim 11, wherein the power supply control circuit includes
a power-on detection circuit that detects power-on of the first power supply, and
a timer that measures a ramp-up time of the first power supply.

14. The semiconductor memory device according to claim 10, wherein the memory cell includes
a first CMOS inverter in which a first drive transistor and a first load transistor are connected in series with each other,
a second CMOS inverter in which a second drive transistor and a second load transistor are connected in series with each other,
a first transfer transistor connected between a first storage node provided at a connection point between the first drive transistor and the first load transistor and a first bit line, and
a second transfer transistor connected between a second storage node provided at a connection point between the second drive transistor and the second load transistor and a second bit line,
wherein output and input of the first CMOS inverter and the second CMOS inverter are cross-coupled to each other, and
a gate of the first transfer transistor and a gate of the second transfer transistor are connected to the word line.

15. The semiconductor memory device according to claim 10, further comprising:
a pull-up circuit that pulls up potentials of the bit lines in a complementary manner;
a pre-charge circuit that pre-charges the bit lines to a high level before reading data from the memory cell;
a read/write circuit that inputs write data based on a write enable signal and outputs read data based on a read enable signal; and
a column selector that connects a bit line specified by a column selection signal to the read/write circuit,
wherein the power supply control circuit boosts the second power supply of the memory cell after boosting the first power supply of the pull-up circuit, the pre-charge circuit, the read/write circuit, and the column selector.

16. A semiconductor memory device comprising:
a memory cell provided with a pair of storage nodes which store data in a complementary manner;
a pair of bit lines that are driven in a complementary manner based on data written to the memory cell;
a word line that selects a row of the memory cell; and
a power supply control circuit that boosts a second power supply of the memory cell before boosting a first power supply that charges the bit lines.

17. The semiconductor memory device according to claim 16, wherein the memory cell includes
a first CMOS inverter in which a first drive transistor and a first load transistor are connected in series with each other,
a second CMOS inverter in which a second drive transistor and a second load transistor are connected in series with each other, p1 a first transfer transistor connected between a first storage node provided at a connection point between the first drive transistor and the first load transistor and a first bit line, and
a second transfer transistor connected between a second storage node provided at a connection point between the second drive transistor and the second load transistor and a second bit line,
wherein output and input of the first CMOS inverter and the second CMOS inverter are cross-coupled to each other, and
a gate of the first transfer transistor and a gate of the second transfer transistor are connected to the word line.

18. The semiconductor memory device according to claim 16, further comprising:
a pull-up circuit that pulls up potentials of the bit lines in a complementary manner;
a pre-charge circuit that pre-charges the bit lines to a high level before reading data from the memory cell;
a read/write circuit that inputs write data based on a write enable signal and outputs read data based on a read enable signal; and
a column selector that connects a bit line specified by a column selection signal to the read/write circuit,
wherein the power supply control circuit boosts the second power supply of the memory cell before boosting the first power supply of the pull-up circuit and the pre-charge circuit.

19. The semiconductor memory device according to claim 18, further comprising:
a row decoder that selects the word line for each row; and
a word line driver that drives the word line selected by the row decoder,
wherein the power supply control circuit boosts the second power supply of the memory cell after boosting a third power supply of the row decoder and the word line driver.

20. The semiconductor memory device according to claim 19, wherein
the word line driver includes an inverter whose output is connected to the word line, and
the row decoder, whose output is connected to an input of the inverter, includes a NAND circuit that performs a negative AND operation between a row selection signal and a clock signal.
